(19) United States
(12) Patent Application Publication
(10) Pub. No.: US 2003/0009302 A1
(43) Pub. Date: Jan. 9, 2003

(54) Method and apparatus for multi-function generator protective relay system

(76) Inventor: David S. Leslie, Buchanan, MI (US)

Correspondence Address: JOHN S. BEULICK, C/O ARMSTRONG TEASDALE, LLP, ONE METROPOLITAN SQUARE, SUITE 2600, ST LOUIS, MO, 63102-2740, US

(21) Appl. No.: 09/682,008

(22) Filed: Jul. 9, 2001

(51) Int. Cl. G06F 19/00; G01R 25/00; G01R 27/00

(52) U.S. Cl. 702/65

(57) ABSTRACT

A method to monitor voltage and current signals using a multi-function generator protective relay system. The method includes measuring at least one of a voltage, a current and a phase angle, and displaying at least one of a relay contact status and the power values on a display.

### BACKGROUND OF INVENTION

This invention relates generally to engine-generator protection systems, and specifically to microprocessor based protection systems that sense electrical voltage and current generated by an engine-generator set.

Engine-generator sets are used to provide an on-site alternate source of electrical energy in hospitals, offices, data centers, factories, institutions, hotels and other buildings where an interruption to the utility source of power may cause unsafe situations or which may result in economic loss. In addition, engine-generator sets may be used to provide electrical energy in remote areas where there is no utility power available. Engine-generator sets may also be used as a distributed source of electrical energy, to reduce the peak load on utility electrical generation systems during peak summer electrical demand periods.

Typically, the engine-generator set is sent a signal to start automatically by an engine-generator control system, without manual intervention, for example upon loss of utility power or at the beginning of a peak demand period. When the engine-generator set develops an abnormal operating condition or malfunction during operation, or when the power generated by the engine-generator set is no longer required, for example upon restoration of utility power or at the end of the peak demand period, the engine-generator set is sent a signal to shutdown by an engine-generator control system.

Enginegenerator control systems utilize devices called protective relays to detect abnormal electrical conditions when an engine-generator set is running and signal the control system to take appropriate action. Protective relays are best illustrated by example. One function of a protective relay is the reverse power function. The reverse power function senses the direction of real power flow. For example, if there are a plurality of engine generators connected together on an electrical bus, and one engine generator stopped running while the other engine generators continued to run, real power would flow into the stopped generator. The real power would then drive the generator like a motor and thereby cause damage to the engine. A reverse power relay can prevent this from happening. In the situation described above, a reverse power relay senses real power flow into the generator and signals the control system to disconnect the engine-generator from the bus thereby preventing damage to the generator.

Prior art engine-generator control systems utilized protective relays with single dedicated functionality. The engine-generator control systems would thus use a plurality of protective relays to achieve the desired detection and control functions. Some prior-art protective relay systems provide multi-function capability.

Known multi-function engine-generator system protective relays typically require a 24 Vdc nominal auxiliary power supply with an 18-28 Vdc operating range. In on-site power generation systems, auxiliary power is normally provided by batteries used to power an engine-generator starter motor. Since a high current is required when the engine-generator starter motor is being cranked, the auxiliary power voltage normally drops below 18 Vdc. Known multi-function engine generator protective relay systems will power-off when this occurs because the auxiliary power voltage drops below the required operating voltage. Loss of power is undesired because data is lost. On-site power generation systems are used in critical power applications where high reliability is required 24 hours a day, seven days a week.

Known engine-generator control systems typically have only one level of security and therefore are unable to discriminate between persons who are desired to have full access to the system and persons who are desired only partial access to the system. For example, field engineers configuring the system may require full access while administrators changing system settings may only require partial access to the system. Further, operators resetting system relays may require even less access to the system.

### SUMMARY OF INVENTION

In one embodiment, a method is provided to monitor voltage and current signals using a multi-function generator protective relay system. The method includes measuring at least one of a voltage, a current and a phase angle, and displaying at least one of a relay contact status and the power values on a display.

In another embodiment, a metering system is provided which comprises a plurality of electrical relays, a display, a microprocessor, a memory, and a plurality printed circuit boards configured to accept voltage and current to be measured. The microprocessor is electrically connected to the memory, the printed circuit boards and the display. The printed circuit boards are electrically connected to a device. The system is configured to continuously monitor voltage, current and frequency to protect the device.

### BRIEF DESCRIPTION OF DRAWINGS

FIG. 1 is a block diagram of an electrical power generation system utilizing multiple engine-generator sets electrically linked together as the source of electrical energy;

FIG. 2 is a block diagram of a multi-function generator protective relay system;

FIG. 3 is a block diagram of a multi-function generator protective relay system electrically connected to an engine-generator set; and

FIG. 4 is an illustration of a set of rear panel electrical connections provided in a preferred embodiment.

### DETAILED DESCRIPTION

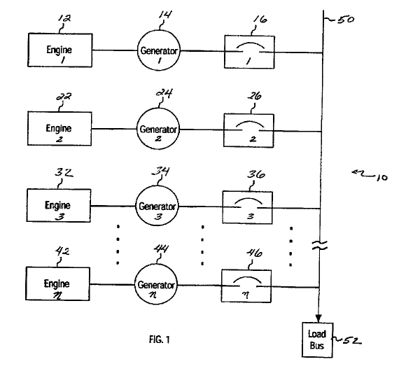

FIG. 1 illustrates a block diagram of an electrical power generation system 10 utilizing multiple engine-generator sets as a source of electrical energy. Each engine-generator set comprises an engine, an electrical generator, and a circuit breaker. In the embodiment shown in FIG. 1, n engine-generator sets are shown where the engines and generators are mechanically linked together. Circuit breakers electrically link the outputs of the n generators. n engine-generator sets are shown in FIG. 1 to illustrate that depending on the required capacity of the electrical power generation system there may be more or less than three engine-generator sets within the system. Again referring to FIG. 1, a first engine-generator set includes a first engine 12, a first generator 14, and a first circuit breaker 16. A second engine-generator set includes a second engine 22, a second generator 24, and a second circuit breaker 26. A third engine-generator set includes a third engine 32, a third generator 34, and a third circuit breaker 36. An n^{th} engine-generator set includes an n^{th} engine 42, an n^{th} generator 44, and an n^{th} circuit breaker 46. The electrical energy of each engine-generator set is linked via circuit breakers to a common electrical bus 50 which is connected to load bus 52 for the distribution of electricity. In a typical engine-generator system as shown in FIG. 1, each engine-generator set is controlled and monitored as described below.

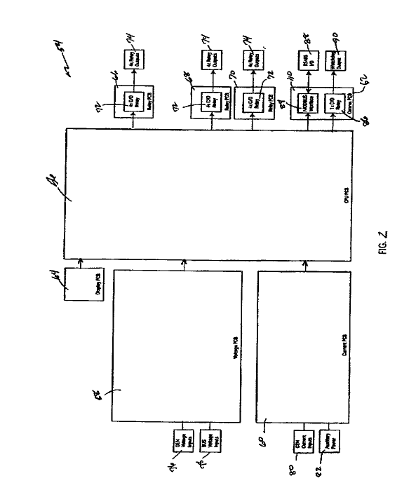

FIG. 2 illustrates a block diagram of a multi-function generator protective relay system 54. CPU Printed Circuit Board (PCB) 56 is electrically connected to a voltage PCB 58, a current PCB 60, a Communication PCB 62, a display PCB 64, and a plurality of relay PCBs 66, 68 and 70. Relay PCBs 66, 68 and 70 include a plurality of changeover relays 72. Changeover relays 72 are connected to relay outputs 74.

CPU PCB 56 includes a microprocessor (not shown) electrically connected to a program memory (not shown) and a data memory (not shown). CPU PCB 56 also includes a watchdog and reset timer (not shown). CPU PCB 56 is connected to Display PCB 64 which includes a display (not shown). Voltage PCB 58 is connected to generator voltage inputs 76 and bus voltage input 78. Current PCB 60 is connected to generator current input 80 and auxiliary power input 82. Communications PCB 62 includes MODBUS interface 84 and changeover relay 86. MODBUS interface 84 is connected to CPU PCB 56 and to RS485 I/O 88. Changeover relay 86 is connected to CPU PCB 56 and to watchdog output 90.

Voltage PCB 58 senses voltage from generator 76 and bus 78. Voltage from generator 76 is filtered to remove any spurious noise from the voltage signal. The voltage signal is then divided by a voltage divider to lower the voltage level equivalent to a digital voltage level for measurement by the microprocessor on CPU PCB 56. Similarly, voltage from bus 78 is input to the voltage PCB 58. As stated above the electrical energy of each engine-generator set is linked via circuit breakers to a common electrical bus 50 which is connected to load bus 52 for the distribution of electricity. Electrical bus 50 voltage is input at voltage bus 78 to voltage PCB 58 where it is filtered to remove any spurious noise on the voltage signal. The voltage signal is then input to a voltage transformer to step down the voltage. The voltage is then further reduced to a level acceptable for input to the microprocessor on CPU PCB 56.

Current from generator 80 is filtered to remove spurious noise. The current is then converted to a current to a level acceptable for input to CPU PCB 56.

Auxiliary power input 82 is connected to current PCB 60, and then transformed to the voltages required to power on board electronic components (not shown) within protective relay system 54. Auxiliary power input 82 is operable over an 8 Vdc to 36 Vdc range. Protective relay system 54 will therefore remain active when auxiliary power input 82 voltage is within the range of 8 Vdc and 36 Vdc. The microprocessor (not shown) located on CPU PCB 56 is electrically connected to a program memory (not shown). A software program is stored in the program memory. The microprocessor executes the stored program. In one embodiment the program memory is a Read-Only Memory (ROM). In an alternative embodiment, the program memory is a Programmable Read-Only Memory (PROM). In a further alternative embodiment the program memory is nonvolatile Random Access Memory (NVRAM). In a still further embodiment, the program memory is volatile Random Access Memory. The program memory is updated through MODBUS interface 84 and RS-485 interface 88. The microprocessor is also electrically connected to a data memory (not shown). In one embodiment, the data memory is volatile memory whose contents are erased upon power-down. The microprocessor reads and writes to the data memory.

The term microprocessor, as used herein, refers to microcontrollers, reduced instruction set circuits (RISC), application specific integrated circuits (ASICs), logic circuits, and any other circuit or processor capable of executing the programs described above.

Display PCB 64 includes a display (not shown). In one embodiment, the display is an 80 character, alphanumeric backlit LCD display that exhibits measured parameters, such as voltage, current, frequency, true RMS values, power, relay identification and status. In addition, CPU PCB 56 is connected to communication PCB 62 which contains MODBUS interface 84 and a changeover relay 86. MODBUS is a communications protocol that is a messaging structure independent of the underlying physical layer. MODBUS has two transmission modes: ASCII and RTU (Remote Terminal Unit). In an exemplary embodiment, the RTU protocol is used because each eight-bit byte in a message is sent as two four-bit hexadecimal characters resulting in a higher throughput. MODBUS interface 84 interfaces RS485 bus 88 to CPU PCB 56. Changeover relay 86 is a combination of a normally open relay contact and a normally closed relay contact. Changeover relay 86 changes the state of both contacts simultaneously. Changeover relay 86 interfaces to watchdog output relay 90. Watchdog output relay 90 performs self-diagnostic checks at power-up, and if an internal fault is detected, e.g., auxiliary power is lost, watchdog relay 90 will send a signal to the control system to open a generator breaker.

Furthermore, there are three relay PCB boards 66, 68, and 70. Each relay PCB includes four changeover relays, 4xC/O relays 72. Relays 72 connect to relay outputs 74 which, in an exemplary embodiment, electrically connects to the control system to control the generator sets. In an alternative embodiment, relay outputs 74 connect to controls for automatic transfer switches. In a further alternative embodiment, relay outputs 74 connect to controls for electric motors. In a still further alternative embodiment, relay outputs 74 connect to controls for power distribution systems.

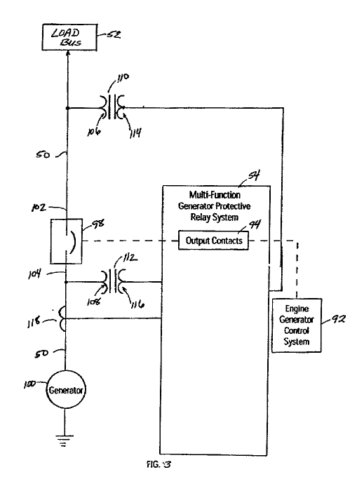

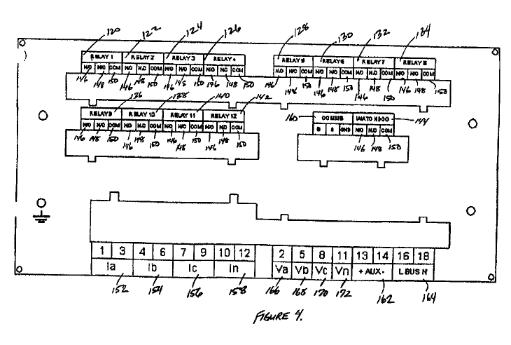

FIG. 3 illustrates a block diagram of a multi-function generator protective relay system 54 electrically connected to an engine-generator. An engine-generator control system 92 is electrically connected in series to a plurality of output contacts 94 within a multi-function generator protective relay system 54. Output contacts 94 include a plurality of relays on a rear panel of the protective relay metering system (one embodiment is shown in FIG. 4). Output contacts 94 are electrically connected to the close and trip circuits of a generator circuit breaker 98. Circuit breaker 98 is electrically connected to a common electrical bus 50 (as shown in FIG. 1) which is connected to load bus 52 (as shown in FIG. 1) for the distribution of electricity produced by generator 100. Circuit breaker 98 divides electrical bus 50 into a load side 102 and a generator side 104. Electrical bus 50 is electrically connected to primary windings 106 and 108 of potential transformers 110 and 112. Secondary windings 114 and 116 of potential transformers 110 and 112 are connected to generator voltage inputs and bus voltage inputs of protective relay system 54. Transformer 110 is connected to load side 102 of electrical bus 50 and transformer 112 is connected to the generator side 104 of electrical bus 50. Secondary windings (not shown) of current transformers 118 are connected to generator current inputs of protective relay system 54. Transformer 118 is connected to the generator side 104 of electrical bus 50.

Multi-function generator protective relay system 54 monitors the voltage and current produced by generator 100 on electrical bus 50. Protective relay system 54 monitors voltage and current by tapping into electrical bus 50 through electrical connections to transformers 110, 112, and 118. Protective relay system 54 is able to monitor both load side 102 and generator side 104 of electrical bus 50. Thus, if the voltage on load side 102 of electrical bus 50 decreases, the corresponding voltage of secondary winding 114 of transformer 110, connected to load side 102 of electrical bus 50, will decrease and the decreased voltage will be detected by protective relay system 54. Likewise, if a voltage decrease is generated on generator side 104 of electrical bus 50, the corresponding voltage of secondary winding 116 of transformer 112, connected to generator side 104 of electrical bus 50, will decrease and the decreased voltage will be detected by protective relay system 54. Similarly, if a fluctuation in current is generated on generator side 104 of electrical bus 50, current transformer 118 connected to generator side 104 of bus 50 will measure a decrease in current and a signal will be transmitted to protective relay system 54.

A plurality of relays (not shown) within protective relay system 54 are configured to measure a synchronization, an under-voltage, a phase sequence, an over-voltage, an over frequency, an under frequency, an AC time over current with voltage restraint, an AC time over current and a reverse power or a boolean combination thereof. In one embodiment, one or a plurality of relays are configured to function as synchronizing relays that can sense when electrical bus 50 is a “dead-bus” having no electrical potential relative to ground.

When an event is detected a date, a time, a relay number and a function or functions assigned to the relay, as well as, the state a relay was in when it was tripped is recorded in an event log. The event log is stored on CPU PCB 56. In one embodiment, the event log records at least ten events in a first-in-first out buffer. In an alternative embodiment, the time resolution is at least 100 milliseconds.

Generator protective relay system 54 includes a multi-level security system (not shown). The multi-level security system requires a person to input a password to access different levels of control of relay system 54. In one embodiment, the security system allows up to four levels of access control of relay system 54, each level accessible through a separate password. For example, in one embodiment, the multi-level security system includes an installation level, an engineering level, an operator level and a total lockout level. In such an embodiment, the installation level allows a person access to complete configuration of relay system 54, the engineering level allows a person to modify only portions of the configuration of relay system 54, the operator level allows only inspection of the configuration of relay system 54 and the total lockout level allows only inspection of the event log and diagnostic information screens.

FIG. 4 illustrates rear panel electrical connections provided in an exemplary embodiment. Four potential transformer inputs 166, 168, 170 and 172 are provided to accept three phase voltage inputs from generator side 104 of electrical bus 50. In addition, one potential transformer input 164 is provided to accept a neutral connection from generator side 104 of electrical bus 50. Four current transformer inputs 152, 154, 156, and 158 are provided to accept three phase and neutral current signals from generator side 104 of electrical bus 50. In addition, all inputs 166, 168, 170, 172, 164, 152, 154, 156 and 158 are electrically isolated from each other and from ground, allowing a connection to a common ground. In one embodiment, all electrical connections are made using two-part removable connection blocks (not shown). Changeover relays 120, 122, 124, 126, 128, 130, 132, 134, 136, 138, 140, 142 and 144 are included. Each changeover relay has a normally open contact 146, a normally closed contact 148, and common connection 150. One of the thirteen changeover relays is configured as a watchdog relay 144. In an exemplary embodiment, each relay is capable of being configured to perform one function or any boolean combination of functions. For example, in one embodiment, the relays can be configured to function as a synchronizing relay, an undervoltage relay, a phase sequence relay, an over-voltage relay, an over frequency relay, an under frequency relay, an AC time over current with voltage restraint relay, an AC time over current relay, a reverse power relay or any boolean combination of the above. In a further embodiment, one or a plurality of relays are configured to function as synchronizing relays that can sense when electrical bus 50 is a “dead-bus” having no electrical potential relative to ground. Aux 162 provides connection to an auxiliary power source, and LBusN 164 provides a connection to load bus 52 (shown in FIG. 2). In addition, terminal connections 166, 168, 170, and 172 are input voltage connections. In one embodiment, three-phase voltage is connected to terminal connections 166, 168, 170, and 172.

In one embodiment, communications port 160 is an electrically isolated 2-wire plus ground electrical interface. In one embodiment, an RS-485 connection is connected to communications port 160.

The methods and apparatus as described herein are not limited to the control and protection of an engine-generator system. Other examples of systems to be monitored and protected include, but are not limited to, automatic transfer switches, distribution protection, and motor protection.

While the invention has been described in terms of various specific embodiments, those skilled in the art will recognize that the invention can be practiced with modification within the spirit and scope of the claims.

1. A method to monitor voltage and current signals using a multi-function generator protective relay system, said method comprising the steps of:
measuring at least one of a voltage, a current and a phase angle;
displaying at least one of a relay contact status and the power values on a display.

2. A method in accordance with claim 1 wherein said step of measuring comprises the step of connecting a plurality of relays having a combination of functions to a device.

3. A method in accordance with claim 1 wherein said step of measuring comprises the step of continuously sampling at least one of a current, a voltage, and a frequency.

4. A method in accordance with claim 1 wherein said step of measuring comprises the step of performing a self-test diagnostic when at least one of a power-up occurs, when an internal fault is detected and an auxiliary power is lost.

5. A method in accordance with claim 1 wherein said step of measuring comprises the step of determining a true root mean square value for at least one of a voltage and a current.

6. A method in accordance with claim 5 wherein said step of determining a root mean square value comprises the step of detecting failures in a generator.

7. A method in accordance with claim 6 wherein said step of detecting failures comprises the step of recording a date and time of failure.

8. A method in accordance with claim 7 wherein said step of detecting failures comprises the step of storing in memory a failure, when a failure occurs.

9. A method in accordance with claim 1 wherein said step of determining a power value comprises the step of opening a circuit breaker when at least one of an internal fault is detected and auxiliary power is lost.

10. A metering system comprising a plurality of electrical relays, a display, a microprocessor, a memory, and a plurality of printed circuit boards configured to accept voltage and current to be measured, said microprocessor electrically connected to the memory, the printed circuit boards, and the display, said printed circuit boards electrically connected to a device, said system configured to continuously monitor voltage, current and frequency to protect the device.

11. A system in accordance with claim 10 wherein said system further comprises a watchdog relay connected to the device to be protected.

12. A system in accordance with claim 11 wherein said watchdog relay configured to perform self-diagnostic checks at power-up.

13. A system in accordance with claim 11 wherein said watchdog relay configured to be connected to a breaker trip circuit, said breaker trip circuit configured to open a breaker when at least one of an internal fault is detected and auxiliary power is lost.

14. A system in accordance with claim 10 wherein said system further comprises an auxiliary power supply connected to a device.

15. A system in accordance with claim 14 wherein said auxiliary power supply configured to operate as a switched mode auxiliary power supply.

16. A system in accordance with claim 10 wherein said relays comprise change over relay contacts, said change over contacts include one normally open contact and one normally closed contact.

17. A system in accordance with claim 10 wherein said system configured to control at least one relay based upon measurements of at least one of a synchronization, synchronization with dead-bus, directional power, phase balance, AC time over, AC time over with voltage restraint, under voltage, phase sequence, neutral ground fault, over voltage, over frequency, and under frequency connected to a device to be monitored and protected.

18. A system in accordance with claim 10 wherein said system configured with an event log, said event log recording a date stamp, a time stamp, a relay number, a function assigned to a relay, and a present parameter when a relay is tripped.

19. A system in accordance with claim 10 wherein said system further comprises an RS-485 communications port.

20. A system in accordance with claim 19 wherein said RS-485 communications port configured as an electrically isolated 2-wire plus ground electrical interface.

21. A system in accordance with claim 10 wherein said display configured to display a status of at least one of a current, a voltage and a frequency for a plurality of relays.

22. A system in accordance with claim 10 wherein said system further comprises current transformer inputs.

23. A system in accordance with claim 22 wherein said current transformer input configured to be electrically isolated from ground and from other current transformers.

24. A system in accordance with claim 15 wherein said auxiliary power supply is operable within a voltage range of 8 Vdc to 36 Vdc.

25. A system in accordance with claim 10 further comprising a multi-level security system configured to allow different levels of access to said metering system through input of a password.
